(19) United States
(12) Patent Application Publication
(10) Pub. No.: US 2016/0013029 A1
(43) Pub. Date: Jan. 14, 2016

(54) Apparatus For Generating Plasma Using Dual Plasma Source And Apparatus For Treating Substrate Including The Same

(71) Applicant: PSK Inc., Gyeonggi-do (KR)

(72) Inventors: Hee Sun Chae, Gyeonggi-do (KR); Jeong Hee Cho, Gyeonggi-do (KR); Jong Sik Lee, Gyeonggi-do (KR); Han Saem Lee, Gyeonggi-do (KR); Hyun Jun Kim, Gyeonggi-do (KR)

(21) Appl. No.: 14/459,179

(22) Filed: Aug. 13, 2014

(30) Foreign Application Priority Data
Jul. 8, 2014 (KR) 10-2014-0085214

(51) Int. Cl. H01J 37/32; H01L 21/67

(52) U.S. Cl. CPC H01J 37/32669; H01L 21/67069; H01J 37/32082; H01J 37/32458; H01J 2237/334

(57) ABSTRACT

The present invention relates to an apparatus for generating plasma using a dual plasma source and a substrate treatment apparatus including the same. A plasma generation apparatus according to an embodiment of the present invention includes: an RF power supply configured to supply an RF signal; a plasma chamber configured to provide a space in which plasma is generated; a first plasma source installed at one part of the plasma chamber to generate plasma; and a second plasma source installed at the other part of the plasma chamber to generate plasma, the second plasma source including: a plurality of insulating loops formed along a circumference of the plasma chamber, wherein a gas passage through which a process gas is injected and moved to the plasma chamber is provided in each insulating loop; and a plurality of electromagnetic field appliers coupled to the insulating loops and receiving the RF signal to excite the process gas moved through the gas passage to a plasma state.

### CROSS-REFERENCE TO RELATED APPLICATIONS

This U.S. non-provisional patent application claims priority under 35 U.S.C. §119 of Korean Patent Application No. 10-2014-0085214, filed on Jul. 8, 2014, the entire contents of which are hereby incorporated by reference.

### BACKGROUND OF THE INVENTION

The present invention disclosed herein relates to an apparatus for generating plasma using a dual plasma source and a substrate treatment apparatus including the same.

A process for treating a substrate using plasma is used to manufacture a semiconductor, a display or a solar cell. For example, an etching apparatus, an ashing apparatus or a cleaning apparatus used for a semiconductor manufacturing process includes a plasma source for generating plasma, and a substrate may be etched, ashed or cleaned by the plasma.

In particular, an inductively coupled plasma (ICP)-type plasma source induces an electromagnetic field in a chamber by allowing a time-varying current to flow through a coil installed at the chamber, and excites gas supplied to the chamber to a plasma state using the induced electromagnetic field. However, according to the ICP-type plasma source, a density of plasma generated in a center region of the chamber is higher than that of plasma generated in an edge region of the chamber. Therefore, a density profile of plasma along the diameter of a substrate is not regular.

Furthermore, a process for treating a large-size substrate having a diameter of about 450 mm has been recently used. Accordingly, the degradation of process yield due to the irregular density of plasma has become an issue. Therefore, it is required to regularly generate plasma throughout a chamber in order to improve the yield of a plasma process.

### SUMMARY OF THE INVENTION

The present invention provides a plasma generation apparatus for regularly generating plasma in a chamber and a substrate treatment apparatus including the same.

The present invention also provides a plasma generation apparatus for controlling a density profile of plasma generated in a chamber and a substrate treatment apparatus including the same.

Embodiments of the present invention provide plasma generation apparatuses including: an RF power supply configured to supply an RF signal; a plasma chamber configured to provide a space in which plasma is generated; a first plasma source installed at one part of the plasma chamber to generate plasma; and a second plasma source installed at the other part of the plasma chamber to generate plasma, the second plasma source including: a plurality of insulating loops formed along a circumference of the plasma chamber, wherein a gas passage through which a process gas is injected and moved to the plasma chamber is provided in each insulating loop; and a plurality of electromagnetic field appliers coupled to the insulating loops and receiving the RF signal to excite the process gas moving through the gas passage to a plasma state.

In some embodiments, the electromagnetic field applier may include: a core formed of a magnetic material and surrounding the insulating loop; and a coil wound on the core.

In other embodiments, the core may include: a first core surrounding a first part of the insulating loop to form a first closed loop; and a second core surrounding a second part of the insulating loop to form a second closed loop.

In still other embodiments, the first core may include: a first subcore forming a half part of the first closed loop; and a second subcore forming the other half part of the first closed loop, and the second core may include: a third subcore forming a half part of the second closed loop; and a fourth subcore forming the other half part of the second closed loop.

In even other embodiments, the plurality of electromagnetic field appliers may be connected to each other in series.

In yet other embodiments, the plurality of electromagnetic field appliers may include a first applier group and a second applier group connected in parallel to each other.

In further embodiments, the plurality of electromagnetic field appliers may be configured so that a turn number of the coil wound on the core is increased in a direction from an input terminal to a grounding terminal.

In still further embodiments, the plurality of electromagnetic field appliers may be configured so that a distance between the first subcore and the second subcore and a distance between the third subcore and the fourth subcore are decreased in a direction from an input terminal to a grounding terminal.

In even further embodiments, an insulator may be inserted between the first subcore and the second subcore and between the third subcore and the fourth subcore.

In yet further embodiments, the second plasma source may include eight electromagnetic field appliers, wherein four of the eight electromagnetic field appliers may be connected to each other in series to form a first applier group, wherein the other four of the eight electromagnetic field appliers may be connected to each other in series to form a second applier group, wherein the first applier group may be connected in parallel to the second applier group, wherein the four electromagnetic field appliers forming the first applier group may have an impedance ratio of 1:1.5:4:8, wherein the four electromagnetic field appliers forming the second applier group may have an impedance ratio of 1:1.5:4:8.

In further embodiments, the coil may include: a first coil wound on one part of the core; and a second coil wound on the other part of the core, wherein the first coil and the second coil may be mutual-inductively coupled.

In still further embodiments, the first coil and the second coil may have the same turn number.

In even further embodiments, the plasma generation apparatus may further include a reactance element connected to a grounding terminal of the second plasma source.

In yet further embodiments, the plasma generation apparatus may further include a phase adjuster provided to nodes between the plurality of electromagnetic field appliers to equally fix a phase of the RF signal at each node.

In yet still much further embodiments, the plasma generation apparatus may further include: a reactance element connected to a grounding terminal of the second plasma source; and a shunt reactance element connected to nodes between the plurality of electromagnetic field appliers. In yet even further embodiments, impedance of the shunt reactance element may be a half of combined impedance of a secondary coil of the mutual-inductively coupled coils and the reactance element.

In yet still even further embodiments, the first plasma source may include an antenna installed on the plasma chamber to induce an electromagnetic field in the plasma chamber.

In yet still even further embodiments, the first plasma source may include electrodes installed in the plasma chamber to form an electric field in the plasma chamber.

In yet still even further embodiments, a process gas including at least one of ammonia and hydrogen may be injected into an upper part of the plasma chamber, wherein a process gas including at least one of oxygen and nitrogen may be injected into the insulating loop.

In other embodiments of the present invention, substrate treatment apparatuses include: a process unit comprising a process chamber and providing a space in which a process is performed, wherein a substrate is arranged in the process chamber; a plasma generation unit configured to generate plasma and provide the plasma to the process unit; and an exhaust unit configured to discharge gas and byproducts in the process unit, the plasma generation unit including: an RF power supply configured to supply an RF signal; a plasma chamber configured to provide a space in which plasma is generated; a first plasma source installed at one part of the plasma chamber to generate plasma; and a second plasma source installed at the other part of the plasma chamber to generate plasma, the second plasma source including: a plurality of insulating loops formed along a circumference of the plasma chamber, wherein a gas passage through which a process gas is injected and moved to the plasma chamber is provided in each insulating loop; and a plurality of electromagnetic field appliers coupled to the insulating loops and receiving the RF signal to excite the process gas moving through the gas passage to a plasma state.

In some embodiments, the electromagnetic field applier may include: a core formed of a magnetic material and surrounding the insulating loop; and a coil wound on the core.

In other embodiments, the core may include: a first core surrounding a first part of the insulating loop to form a first closed loop; and a second core surrounding a second part of the insulating loop to form a second closed loop.

In still other embodiments, the first core may include: a first subcore forming a half part of the first closed loop; and a second subcore forming the other half part of the first closed loop, and the second core may include: a third subcore forming a half part of the second closed loop; and a fourth subcore forming the other half part of the second closed loop.

In even other embodiments, the plurality of electromagnetic field appliers may be connected to each other in series.

In yet other embodiments, the plurality of electromagnetic field appliers may include a first applier group and a second applier group connected in parallel to each other.

In further embodiments, the plurality of electromagnetic field appliers may be configured so that a turn number of the coil wound on the core is increased in a direction from an input terminal to a grounding terminal.

In still further embodiments, the plurality of electromagnetic field appliers may be configured so that a distance between the first subcore and the second subcore and a distance between the third subcore and the fourth subcore are decreased in a direction from an input terminal to a grounding terminal.

In even further embodiments, an insulator may be inserted between the first subcore and the second subcore and between the third subcore and the fourth subcore.

In yet further embodiments, the second plasma source may include eight electromagnetic field appliers, wherein four of the eight electromagnetic field appliers may be connected to each other in series to form a first applier group, wherein the other four of the eight electromagnetic field appliers may be connected to each other in series to form a second applier group, wherein the first applier group may be connected in parallel to the second applier group, wherein the four electromagnetic field appliers forming the first applier group may have an impedance ratio of 1:1.5:4:8, wherein the four electromagnetic field appliers forming the second applier group may have an impedance ratio of 1:1.5:4:8.

In further embodiments, the coil may include: a first coil wound on one part of the core; and a second coil wound on the other part of the core, wherein the first coil and the second coil may be mutual-inductively coupled.

In still further embodiments, the first coil and the second coil may have the same turn number.

In even further embodiments, the substrate treatment apparatus may further include a reactance element connected to a grounding terminal of the second plasma source.

In yet further embodiments, the substrate treatment apparatus may further include a phase adjuster provided to nodes between the plurality of electromagnetic field appliers to equally fix a phase of the RF signal at each node.

In yet still further embodiments, the substrate treatment apparatus may further include: a reactance element connected to a grounding terminal of the second plasma source; and a shunt reactance element connected to nodes between the plurality of electromagnetic field appliers.

In yet even further embodiments, impedance of the shunt reactance element may be a half of combined impedance of a secondary coil of the mutual-inductively coupled coils and the reactance element.

In yet still even further embodiments, the first plasma source may include an antenna installed on the plasma chamber to induce an electromagnetic field in the plasma chamber.

In yet still even further embodiments, the first plasma source may include electrodes installed in the plasma chamber to form an electric field in the plasma chamber.

In yet still even further embodiments, a process gas including at least one of ammonia and hydrogen may be injected into an upper part of the plasma chamber, wherein a process gas including at least one of oxygen and nitrogen may be injected into the insulating loop.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a schematic diagram exemplarily illustrating a substrate treatment apparatus according to an embodiment of the present invention;

FIG. 2 is a diagram illustrating a plane view of a second plasma source according to an embodiment of the present invention;

FIG. 3 is a diagram illustrating an internal structure of an insulating loop according to an embodiment of the present invention;

FIG. 4 is a diagram illustrating a front view of an electromagnetic field applier according to an embodiment of the present invention;

FIG. 5 is a circuit diagram illustrating an equivalent circuit of a second plasma source according to an embodiment of the present invention;

FIG. 6 is a diagram illustrating a plane view of a second plasma source according to another embodiment of the present invention;

FIG. 7 is a circuit diagram illustrating an equivalent circuit of a second plasma source according to another embodiment of the present invention;

FIG. 8 is a diagram illustrating a front view of an electromagnetic field applier according to still another embodiment of the present invention;

FIG. 9 is a circuit diagram illustrating an equivalent circuit of a second plasma source according to still another embodiment of the present invention;

FIG. 10 is a circuit diagram illustrating an equivalent circuit of a second plasma source according to still another embodiment of the present invention;

FIG. 11 is a circuit diagram illustrating an equivalent circuit of a second plasma source according to still another embodiment of the present invention;

FIG. 12 is a diagram illustrating a plane view of a second plasma source according to still another embodiment of the present invention;

FIG. 13 is a diagram illustrating a front view of an electromagnetic field applier according to still another embodiment of the present invention;

FIG. 14 is a circuit diagram illustrating an equivalent circuit of a second plasma source according to still another embodiment of the present invention; and

FIG. 15 is a graph illustrating density profiles of first plasma generated by a first plasma source, second plasma generated by a second plasma source, and plasma finally generated in a chamber by the first and second plasma sources.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

The terms (including technical or scientific terms) used herein have the meanings generally accepted in the art, unless otherwise defined. The terms defined in general dictionaries may be interpreted as having the same meanings as those of the terms used in the related art and/or the present disclosure, and should not be interpreted in an idealized or overly formal sense unless otherwise defined explicitly.

The terminology used herein is not for delimiting the embodiments of the present invention but for describing the embodiments of the present invention. The terms of a singular form may include plural forms unless otherwise specified. The meaning of “include,” “comprise,” “including,” or “comprising,” specifies a composition, an ingredient, a component, a step, an operation and/or an element but does not exclude other compositions, ingredients, components, steps, operations and/or elements.

The term “and/or” used herein indicates each of listed elements or various combinations thereof.

Hereinafter, the embodiments of the present invention will be described in detail with reference to the accompanying drawings.

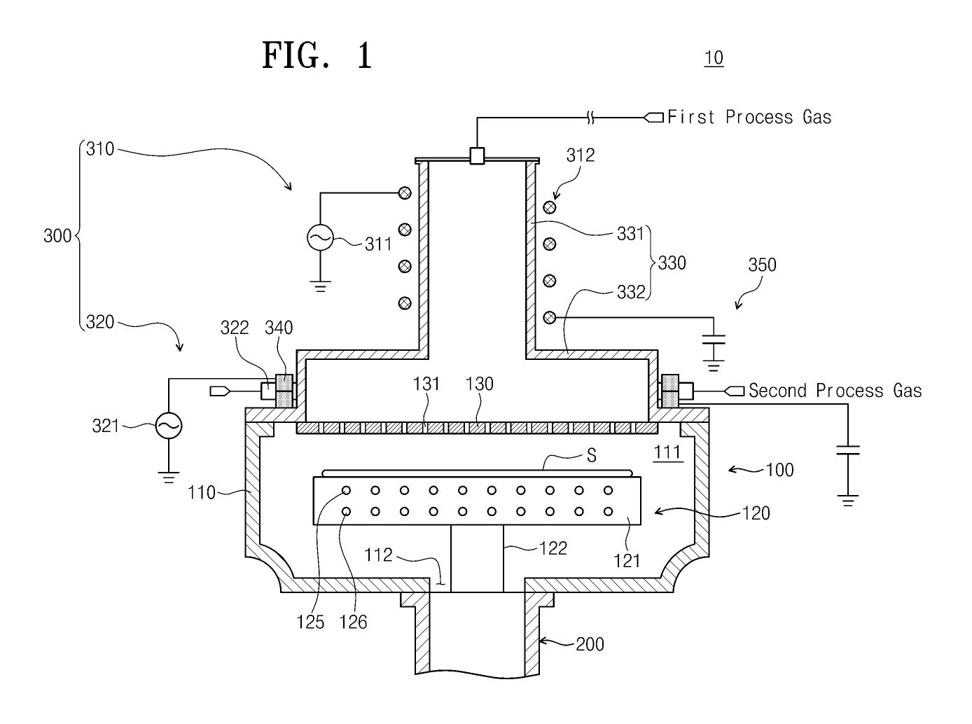

FIG. 1 is a schematic diagram exemplarily illustrating a substrate treatment apparatus 10 according to an embodiment of the present invention.

Referring to FIG. 1, a substrate treatment apparatus 10 may treat, for example, etch or ash, a thin film on a substrate S using plasma. The thin film to be etched or ashed may be a nitride film, for example, a silicon nitride film. However, the thin film to be treated is not limited thereto and may be various films according to a process.

The substrate treatment apparatus 10 may have a process unit 100, an exhaust unit 200, and a plasma generation unit 300. The process unit 100 may provide a space in which the substrate is placed and an etching or ashing process is performed. The exhaust unit 200 may discharge, to the outside, a process gas remaining in the process unit 100 and reaction byproducts generated while treating the substrate, and may maintain a pressure in the process unit 100 as a set pressure. The plasma generation unit 300 may generate plasma from an externally supplied process gas, and may supply the plasma to the process unit 100.

The process unit 100 may have a process chamber 110, a substrate supporting part 120, and a baffle 130. A treatment space 111 for performing a substrate treatment process may be formed in the process chamber 110. An upper wall of the process chamber 110 may be opened, and an opening (not illustrated) may be formed in a side wall of the process chamber 110. The substrate may enter or exit from the process chamber 110 through the opening. The opening may be opened or closed by an opening/closing member such as a door (not illustrated). An exhaust hole 112 may be formed in a bottom surface of the process chamber 110. The exhaust hole 112 is connected to the exhaust unit 200, and may provide a passage through which the gas remaining in the process chamber 110 and the reaction byproducts are discharged to the outside.

The substrate supporting part 120 may support the substrate S. The substrate supporting part 120 may include a susceptor 121 and a supporting shaft 122. The susceptor 121 may be arranged in the treatment space 111 and may have the shape of a disk. The susceptor 121 may be supported by the supporting shaft 122. The substrate S may be placed on an upper surface of the susceptor 121. An electrode (not illustrated) may be provided in the susceptor 121. The electrode is connected to an external power supply, and may generate static electricity by means of applied power. The generated static electricity may fix the substrate S to the susceptor 121. A heating member 125 may be provided in the susceptor 121. For example, the heating member 125 may be a heating coil. Furthermore, a cooling member 126 may be provided in the susceptor 121. The cooling member may be provided as a cooling line through which cooling water flows. The heating member 125 may heat the substrate S to a preset temperature. The cooling member 126 may forcibly cool the substrate S. The substrate S for which a process treatment is completed may be cooled to a room temperature or a temperature required for a next process.

The baffle 130 may be positioned on the susceptor 121. Holes 131 may be formed in the baffle 130. The holes 131 may be provided as through-holes passing through the baffle 130 from an upper surface to a lower surface of the baffle 130, and may be regularly distributed in each region of the baffle 130.

The plasma generation unit 300 may be arranged on the process chamber 110. The plasma generation unit 300 may generate plasma by discharging a process gas, and may supply the generated plasma to the treatment space 111. The plasma generation unit 300 may include RF power supplies 311 and 321, a plasma chamber 330, a first plasma source 310, and a second plasma source 320. The first plasma source 310 may be installed at one part 331 of the plasma chamber 330 so as to excite a first process gas to a plasma state. The second plasma source 320 may be installed at the other part 332 of the plasma chamber 330 so as to excite a second process gas to a plasma state.

Here, the first process gas supplied to the first plasma source 310 may include at least one of ammonia (NH₃) and hydrogen (H₂). The second process gas supplied to the second plasma source 320 may include at least one of oxygen (O₂) and nitrogen (N₂).

The plasma chamber 330 may be arranged on the process chamber 110 so as to be coupled thereto. The plasma chamber 330 may be supplied with a process gas for generating plasma.

According to an embodiment, the first plasma source 310 may be installed at the upper part 331 of the plasma chamber 330, and the second plasma source 320 may be installed at the lower part 332 of the plasma chamber 330.

The first plasma source 310 may include an antenna 312 for inducing an electromagnetic field in the chamber. In this case, the antenna 312 may receive an RF signal from the RF power supply 311 so as to induce the electromagnetic field in the chamber.

However, the first plasma source 310 is not limited to the above-mentioned ICP-type source, and may be a capacitive coupling plasma (CCP)-type source depending on an embodiment. In this case, the first plasma source 310 includes electrodes installed in the chamber so as to form electric fields.

On the contrary, the second plasma source 320 according to an embodiment of the present invention excites a process gas to a plasma state using a plurality of insulating loops 322 and a plurality of electromagnetic field appliers 340 coupled thereto.

Reactance elements 350 such as capacitors may be connected to a grounding terminal of the first plasma source 310 and a grounding terminal of the second plasma source 320. The reactance element 350 may be a fixed reactance element of which impedance is fixed, or may be a variable reactance element of which impedance is variable depending on an embodiment.

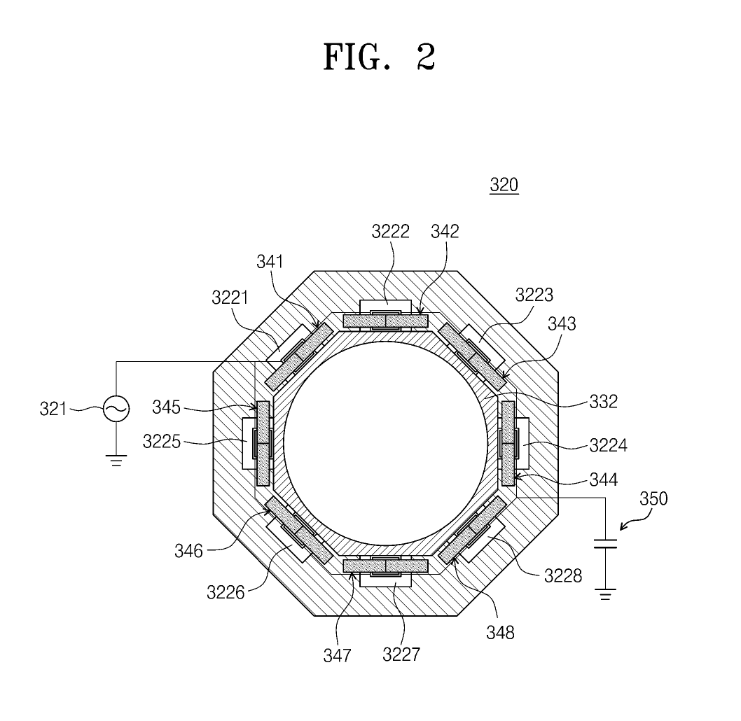

FIG. 2 is a diagram illustrating a plane view of the second plasma source 320 according to an embodiment of the present invention.

As illustrated in FIG. 2, the second plasma source 320 may include a plurality of insulating loops 3221 to 3228 and a plurality of electromagnetic field appliers 341 to 348.

The plurality of insulating loops 3221 to 3228 are formed along the circumference of the plasma chamber 330. The plurality of electromagnetic field appliers 341 to 348 are coupled to the insulating loops 3221 to 3228 and receive the RF signal from the RF power supply 321 so as to excite a process gas to a plasma state.

According to an embodiment, the RF power supply 321 may generate the RF signal to output the RF signal to the electromagnetic field appliers 341 to 348. The RF power supply 321 may transfer high-frequency power for generating plasma using the RF signal. According to an embodiment of the present invention, the RF power supply 321 may generate and output a sinusoidal RF signal, but the RF signal is not limited thereto and may have various waveforms such as a square wave, a triangle wave, a sawtooth wave, and a pulse wave.

The plasma chamber 330 may provide a space where plasma is generated. According to an embodiment, an outer wall of the plasma chamber 330 may have a polygonal cross section. For example, as illustrated in FIG. 2, the plasma chamber 330 may have the outer wall having an octagonal cross section, but the shape of the cross section is not limited thereto.

According to an embodiment of the present invention, the shape of the cross section of the outer wall of the plasma chamber 330 may be determined according to the number of electromagnetic field appliers arranged in the chamber. For example, as illustrated in FIG. 2, in the case where the outer wall of the plasma chamber 330 has an octagonal cross section, the electromagnetic field appliers 341 to 348 may be arranged on side walls corresponding to the sides of the octagon.

As described above, in the case where the outer wall of the plasma chamber 330 has a polygonal cross section, the number of the sides of the polygon may match the number of electromagnetic field appliers. Furthermore, as illustrated in FIG. 2, an inner wall of the plasma chamber 330 may have a circular cross section, but the shape of the cross section of the inner wall is not limited thereto.

The electromagnetic field appliers 341 to 348 may be arranged at the plasma chamber 330, and may receive the RF signal from the RF power supply 321 so as to induce electromagnetic fields. The electromagnetic field appliers 341 to 348 may be arranged at the plasma chamber 330 using the insulating loops 3221 to 3228 formed on the circumference of the plasma chamber 330.

For example, as illustrated in FIG. 2, the plurality of insulating loops 3221 to 3228 may be provided to the circumference of the plasma chamber 330. The insulating loops 3221 3228 are made of insulators such as quartz or ceramic, but are not limited thereto.

The plurality of insulating loops 3221 to 3228 may be formed along the circumference of the plasma chamber 330. For example, as illustrated in FIG. 2, the plurality of insulating loops 3221 to 3228 may be installed on the outer wall of the plasma chamber 330 at regular intervals. Although the second plasma source 320 illustrated in FIG. 2 include eight insulating loops, the number of the insulating loops may be changed depending on an embodiment.

The insulating loops 3221 to 3228 may form a closed loop together with the outer wall of the plasma chamber 330. For example, as illustrated in FIG. 2, the plurality of insulating loops 3221 to 3228 may be shaped like ‘ [symbol] ’ or ‘U’, and may form a closed loop when the insulating loops 3221 to 3228 are installed on the outer wall of the plasma chamber 330.

According to an embodiment of the present invention, a passage through which a process gas is allowed to be moved may be arranged in the insulating loops 3221 to 3228.

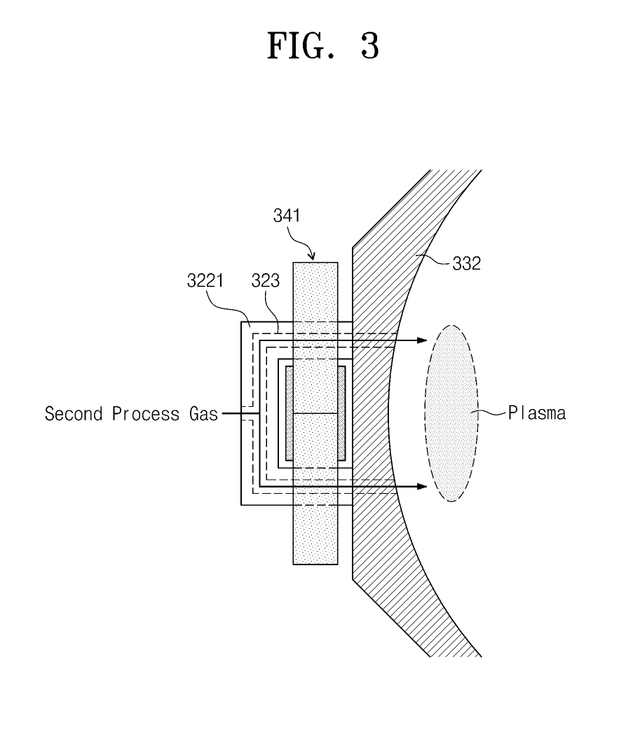

FIG. 3 is a diagram illustrating an internal structure of the insulating loop 3221 according to an embodiment of the present invention.

As illustrated in FIG. 3, a gas passage 323 is arranged in the insulating loop 3221 so that a process gas supplied to the insulating loop 3221 is moved to the plasma chamber 330 through the gas passage 323. That is, the inside of the insulating loop 3221 is formed so as to have a certain empty space, and the process gas is moved through the empty space so as to be supplied to the plasma chamber 330.

Furthermore, according to an embodiment of the present invention, the process gas moved in the insulating loop 3221 may be changed to plasma by the electromagnetic field applier 341 coupled to the insulating loop 3221 so as to be supplied to the chamber 330. As described below, the electromagnetic field applier 341 includes a core and a coil wound around the core, and receives the RF signal from the RF power supply 321 so as to induce an electromagnetic field over the insulating loop 3221. The process gas is excited to a plasma state by the induced electromagnetic field while being moved through the insulating loop 3221.

As described above, the first process gas supplied to the first plasma source 310 may include at least one of ammonia and hydrogen, and the second process gas supplied to the second plasma source 320 may include at least one of oxygen and nitrogen. If the first process gas such as ammonia or hydrogen is supplied to the second plasma source 320, plasma generated from the gas may damage the insulating loop 3221 while passing through the insulating loop 3221.

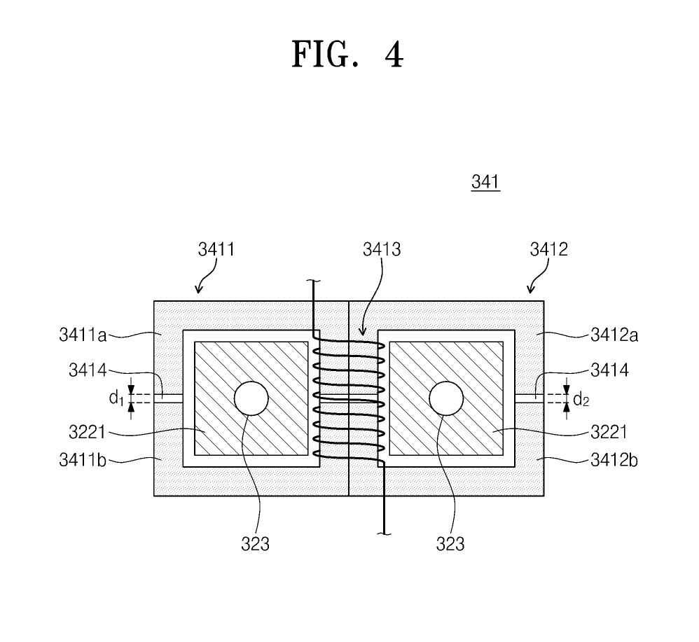

FIG. 4 is a diagram illustrating a front view of the electromagnetic field applier 341 according to an embodiment of the present invention.

The electromagnetic field applier 341 may include cores 3411 and 3412 formed of a magnetic material and surrounding the insulating loop 3221, and a coil 3413 wound around the cores 3411 and 3412. According to an embodiment, the cores 3411 and 3412 may be formed of ferrite, but the material of the cores is not limited thereto.

As illustrated in FIG. 4, the cores may include the first core 3411 and the second core 3412. The first core 3411 may surround a first part of the insulating loop 3221 so as to form a first closed loop. The second core 3412 may surround a second part of the insulating loop 3221 so as to form a second closed loop.

In this case, the coil 3413 may be wound on the first and second cores 3411 and 3412.

According to an embodiment, the first core 3411 and the second core 3412 may be adjacent to each other. For example, as illustrated in FIG. 4, the first core 3411 and the second core 3412 may contact with each other. However, the first core 3411 and the second core 3412 may be spaced apart from each other by a predetermined distance depending on an embodiment.

According to an embodiment of the present invention, the first core 3411 may include a first subcore 3411a that forms a half of the first closed loop and a second subcore 3411b that forms the other half of the first closed loop. The second core 3412 may include a third subcore 3412a that forms a half of the second closed loop and a fourth subcore 3412b that forms the other half of the second closed loop.

As described above, each of the first core 3411 and the second core 3412 may include two or more components, but may be formed as one piece depending on an embodiment.

As described above, the electromagnetic field applier 341 may receive the RF signal so as to induce an electromagnetic field in the insulating loop 3221. The RF signal output from the RF power supply 321 is applied to the coil 3413 of the electromagnetic field applier 341 so as to form an electromagnetic field along the cores 3411 and 3412, wherein the electromagnetic field induces an electric field in the insulating loop 3221.

According to an embodiment, the plurality of electromagnetic field appliers 341 to 348 may include a first applier group and a second applier group, wherein the first applier group may be connected in parallel to the second applier group.

In detail, some of the plurality of electromagnetic field appliers 341 to 348 may be connected to each other in series so as to form the first applier group, and the other electromagnetic field appliers may be connected to each other in series so as to form the second applier group, wherein the first applier group and the second applier group may be connected to each other in parallel.

For example, as illustrated in FIG. 2, the second plasma source 320 may include eight electromagnetic field appliers 341 to 348, wherein four of the electromagnetic field appliers (341 to 344) may be connected to each other in series so as to form the first applier group, and the four other electromagnetic field appliers (345 to 348) may be connected to each other in series so as to form the second applier group. Furthermore, as illustrated in FIG. 2, the first applier group may be connected in parallel to the second applier group.

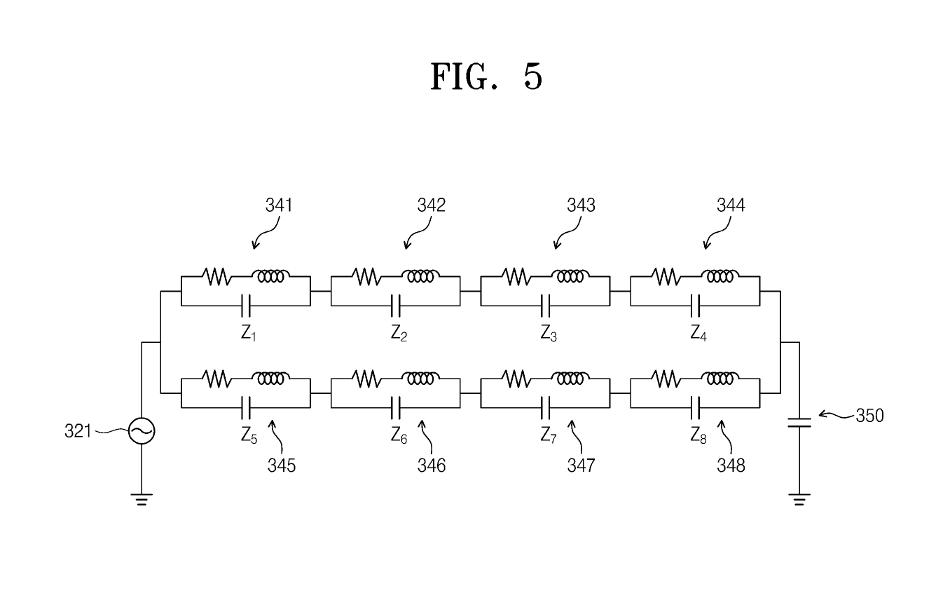

FIG. 5 is a circuit diagram illustrating an equivalent circuit of the second plasma source 320 according to an embodiment of the present invention.

As illustrated in FIG. 5, each electromagnetic field applier may be represented by a resistor, an inductor and a capacitor. The four electromagnetic field appliers 341 to 344 forming the first applier group may be connected to each other in series, and the four electromagnetic field appliers 345 to 348 forming the second applier group may be connected to each other in series. Furthermore, the first applier group may be connected in parallel to the second applier group.

According to an embodiment of the present invention, the plurality of electromagnetic field appliers 341 to 348 may be configured so that impedance is increased in a direction from an input terminal to a grounding terminal.

For example, referring to FIG. 5, with respect to the electromagnetic field appliers 341 to 344 included in the first applier group, impedance Z1 of the first electromagnetic field applier 341 that is closest to the input terminal is lowest, impedance Z2 of the second electromagnetic field applier 342 that is second closest to the input terminal is second lowest, impedance Z3 of the third electromagnetic field applier 343 that is third closest to the input terminal is third lowest, and impedance Z4 of the fourth electromagnetic field applier 344 that is closest to the grounding terminal is highest (Z1<Z2<Z3<Z4).

Furthermore, with respect to the electromagnetic field appliers 345 to 348 included in the second applier group, impedance Z5 of the fifth electromagnetic field applier 345 that is closest to the input terminal is lowest, impedance Z6 of the sixth electromagnetic field applier 346 that is second closest to the input terminal is second lowest, impedance Z7 of the seventh electromagnetic field applier 347 that is third closest to the input terminal is third lowest, and impedance Z8 of the eighth electromagnetic field applier 348 that is closest to the grounding terminal is highest (Z5<Z6<Z7<Z8).

According to an embodiment of the present invention, corresponding electromagnetic field appliers between the applier groups connected in parallel to each other may have the same impedance.

For example, referring to FIG. 4, with respect to the first and second applier groups connected in parallel to each other, the first electromagnetic field applier 341 and the fifth electromagnetic field applier 345 that are closest to the input terminal may have the same impedance (Z1=Z5). Likewise, the second electromagnetic field applier 342 and the sixth electromagnetic field applier 346 that are second closest to the input terminal may have the same impedance (Z2=Z6). Furthermore, the third electromagnetic field applier 343 and the seventh electromagnetic field applier 347 that are third closest to the input terminal may have the same impedance (Z3=Z7). Lastly, the fourth electromagnetic field applier 344 and the eighth electromagnetic field applier 348 that are closest to the grounding terminal may have the same impedance (Z4=Z8).

According to an embodiment of the present invention, the plurality of electromagnetic field appliers may be configured so that a turn number of the coil 3413 is increased in a direction from the input terminal to the grounding terminal. As the turn number of the coil 3413 is increased, the inductance of the coil is increased, and the plurality of electromagnetic field appliers 341 to 348 may be configured so that impedance is increased in a direction from the input terminal to the grounding terminal.

For example, referring to FIG. 2, with respect to the four electromagnetic field appliers 341 to 344 forming the first applier group, the turn number of the coil may be increased in order of the first electromagnetic field applier 341, the second electromagnetic field applier 342, the third electromagnetic field applier 343, and the fourth electromagnetic field applier 344.

Likewise, referring to FIG. 2, with respect to the four electromagnetic field appliers 345 to 348 forming the second applier group, the turn number of the coil may be increased in order of the fifth electromagnetic field applier 345, the sixth electromagnetic field applier 346, the seventh electromagnetic field applier 347, and the eighth electromagnetic field applier 348.

Furthermore, corresponding electromagnetic field appliers between the first applier group and the second applier group may have the same coil turn number. That is, the first electromagnetic field applier 341 and the fifth electromagnetic field applier 345 may have the same coil turn number, the second electromagnetic field applier 342 and the sixth electromagnetic field applier 346 may have the same coil turn number, the third electromagnetic field applier 343 and the seventh electromagnetic field applier 347 may have the same coil turn number, and the fourth electromagnetic field applier 344 and the eighth electromagnetic field applier 348 may have the same coil turn number.

According to another embodiment, the plurality of electromagnetic field appliers may be configured so that a distance d1 between the first subcore 3411a and the second subcore 3411b and a distance d2 between the third subcore 3412a and the fourth subcore 3412b are decreased in a direction from the input terminal to the grounding terminal. As the distances d1 and d2 are increased, a coefficient of coupling between a core and a coil is decreased, thereby reducing inductance. Furthermore, as the inductance is decreased, the impedance of an electromagnetic field applier is decreased. Therefore, the plurality of electromagnetic field appliers 341 to 348 may be configured so that the impedance is increased in a direction from the input terminal to the grounding terminal.

For example, referring to FIG. 2, with respect to the four electromagnetic field appliers 341 to 344 forming the first applier group, the distances d1 and d2 may be decreased in order of the first electromagnetic field applier 341, the second electromagnetic field applier 342, the third electromagnetic field applier 343, and the fourth electromagnetic field applier 344.

Likewise, referring to FIG. 2, with respect to the four electromagnetic field appliers 345 to 348 forming the second applier group, the distances d1 and d2 may be decreased in order of the fifth electromagnetic field applier 345, the sixth electromagnetic field applier 346, the seventh electromagnetic field applier 347, and the eighth electromagnetic field applier 348.

Furthermore, corresponding electromagnetic field appliers between the first applier group and the second applier group may have the same distances. That is, the first electromagnetic field applier 341 and the fifth electromagnetic field applier 345 may have the same distances, the second electromagnetic field applier 342 and the sixth electromagnetic field applier 346 may have the same distances, the third electromagnetic field applier 343 and the seventh electromagnetic field applier 347 may have the same distances, and the fourth electromagnetic field applier 344 and the eighth electromagnetic field applier 348 may have the same distances.

As described above, in the plurality of electromagnetic field appliers 341 to 348, the coil turn number is increased or the distance between cores is decreased in a direction from the input terminal to the grounding terminal, and thus, the impedance may be increased. However, depending on an embodiment, the coil turn number may be increased along with the decrease of the distance between cores in a direction from the input terminal to the grounding terminal. In this case, the impedance of the electromagnetic field applier may be coarsely adjusted by the coil turn number, and may be finely adjusted by the distance between cores.

According to an embodiment of the present invention, an insulator may be inserted between cores of the electromagnetic field applier.

For example, as illustrated in FIG. 4, insulators 3414 may be inserted between the first subcore 3411a and the second subcore 3411b and between the third subcore 3412a and the fourth subcore 3412b. The insulator may be a tape made of an insulating material. In this case, one or more sheets of insulating tape may be attached between cores so as to adjust the distances d1 and d2 between cores.

Referring back to FIGS. 2 and 5, the second plasma source 320 according to an embodiment of the present invention may include eight electromagnetic field appliers 341 to 348, wherein four of the electromagnetic field appliers (341 to 344) may be connected to each other in series so as to form the first applier group, and the four other electromagnetic field appliers (345 to 348) may be connected to each other in series so as to form the second applier group. The first applier group may be connected in parallel to the second applier group.

The four electromagnetic field appliers 341 to 344 forming the first applier group may have an impedance ratio of 1:1.5:4:8, and the four electromagnetic field appliers 345 to 348 forming the second applier group may have an impedance ratio of 1:1.5:4:8 (Z1:Z2:Z3:Z4=Z5:Z6:Z7:Z8=1:1.5:4:8).

Although the second plasma source 320 illustrated in FIGS. 2 and 5 include eight electromagnetic field appliers in total, the number of the electromagnetic field appliers is not limited thereto and thus may be greater than or smaller than eight.

Furthermore, although the second plasma source 320 illustrated in FIGS. 2 and 5 include two applier groups connected in parallel to each other, the number of the applier groups connected in parallel to each other may be greater than two. For example, the second plasma source 320 may include nine electromagnetic field appliers in total, and three of the electromagnetic field appliers form a single applier group, thereby forming there applier groups in total. The three applier groups may be connected in parallel to each other.

Unlike the embodiment illustrated in FIGS. 2 and 5, the plurality of electromagnetic field appliers may be connected to each other in series.

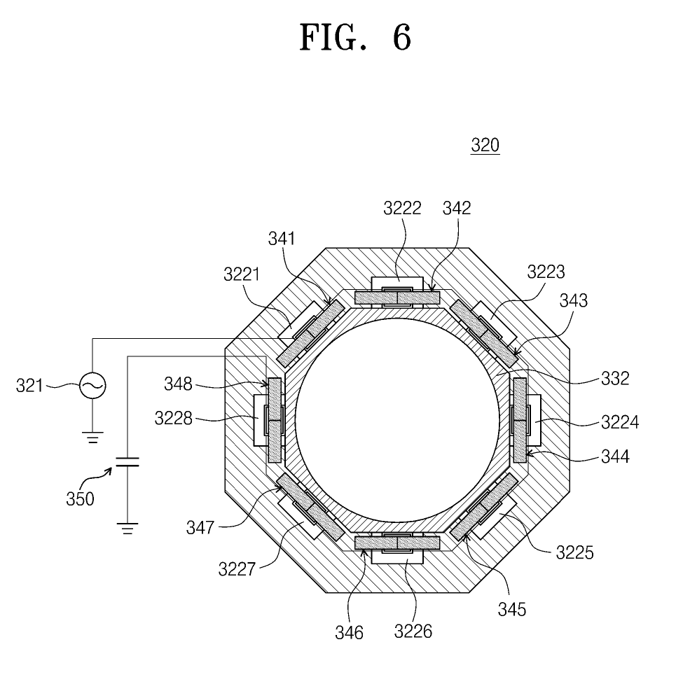

FIG. 6 is a diagram illustrating a plane view of the second plasma source 320 according to another embodiment of the present invention.

Referring to FIG. 6, the second plasma source 320 may include a plurality of electromagnetic field appliers 341 to 348. However, unlike the embodiment illustrated in FIG. 2, all of the plurality of electromagnetic field appliers 341 to 348 may be connected to each other in series.

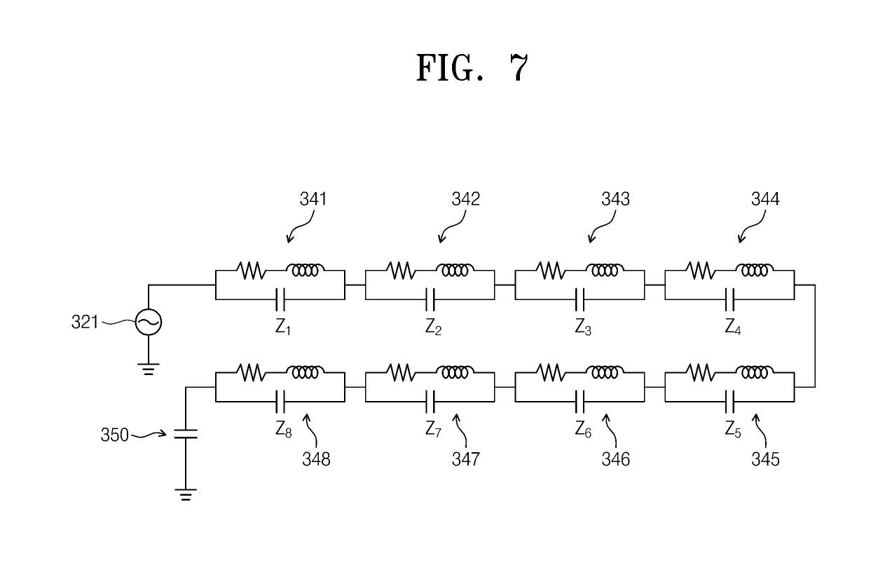

FIG. 7 is a circuit diagram illustrating an equivalent circuit of the second plasma source 320 according to the other embodiment of the present invention.

As illustrated in FIG. 7, the plurality of electromagnetic field appliers 341 to 348 may be connected to each other in series. Furthermore, the plurality of electromagnetic field appliers 341 to 348 may be configured so that impedance is increased in a direction from an input terminal to a grounding terminal. In other words, the impedance may be increased in ascending order of distance to the input terminal, i.e., in order of the first electromagnetic field applier 341, the second electromagnetic field applier 342, the third electromagnetic field applier 343, the fourth electromagnetic field applier 344, the fifth electromagnetic field applier 345, the sixth electromagnetic field applier 346, the seventh electromagnetic field applier 347, and the eighth electromagnetic field applier 348 (Z1<Z2<Z3<Z4<Z5<Z6<Z7<Z8).

In the above-mentioned embodiments, the one coil 3413 is wound on the cores 3411 and 3412 included in an electromagnetic field applier. However, according to another embodiment, a plurality of coils may be wound on the cores 3411 and 3412 so as to be mutual-inductively coupled.

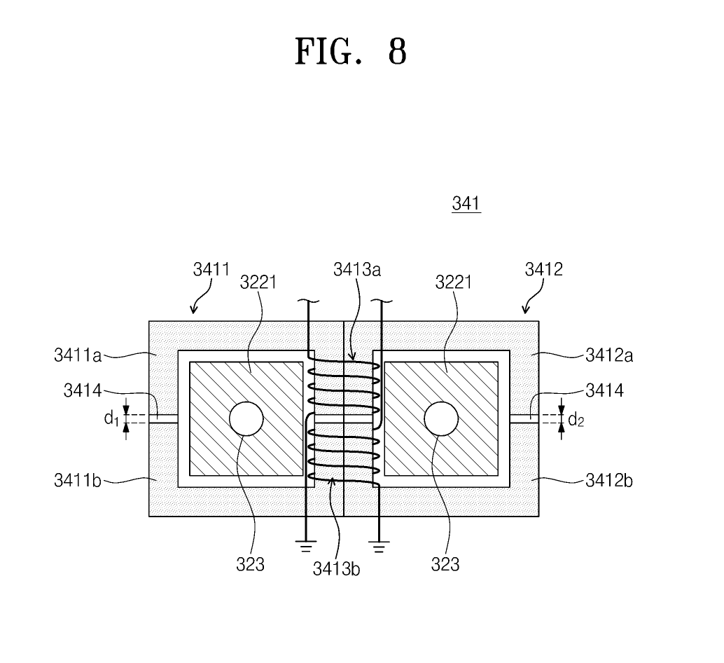

FIG. 8 is a diagram illustrating a front view of the electromagnetic field applier 341 according to still another embodiment of the present invention.

Referring to FIG. 8, the coils included in the electromagnetic field applier 341 include a first coil 3413a wound on one part of the cores 3411 and 3412 and a second coil 3413b wound on the other part of the cores 3411 and 3412, wherein the first coil 3413a and the second coil 3413b may be mutual-inductively coupled.

The first core 3411 and the second coil 3412 may contact with each other, and the first coil 3413a and the second coil 3413b may be wound on a contact portion between the first core 3411 and the second core 3412.

As described above, the first coil 3413a and the second coil 3413b share the coils and are wound thereon while being separated from each other, so that the first coil 3413a and the second coil 3413b are mutual-inductively coupled.

According to an embodiment, the coils included in each electromagnetic field applier, for example, the first coil 3413a and the second coil 3413b, may have the same turn number. In other words, the two coils that are mutual-inductively coupled may have a turn ratio of 1:1.

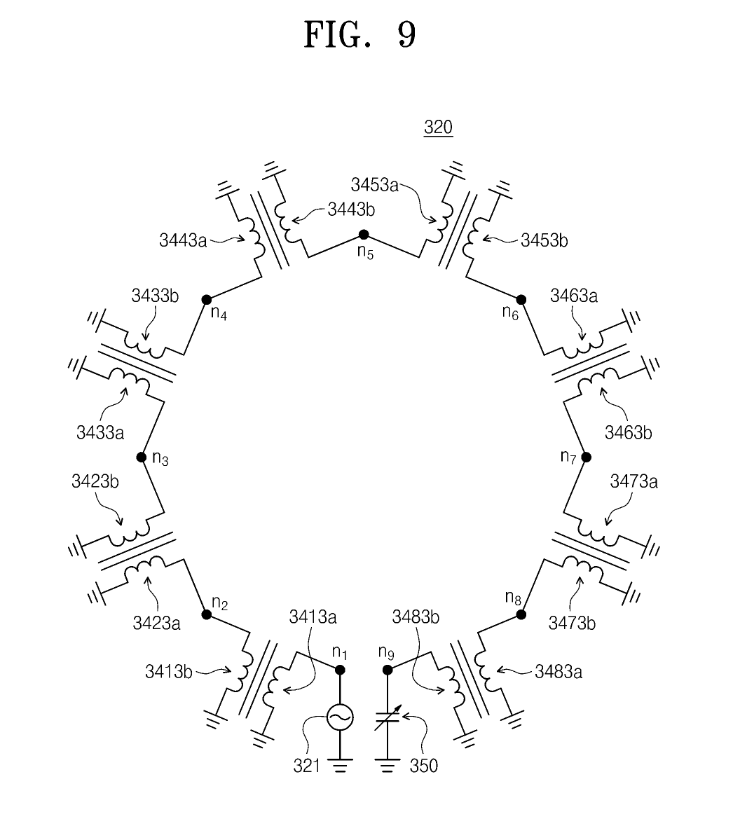

FIG. 9 is a circuit diagram illustrating an equivalent circuit of the second plasma source 320 according to the still other embodiment of the present invention.

As illustrated in FIG. 9, the first and second coils included in each electromagnetic field applier are mutual-inductively coupled and have a turn ratio of 1:1. Therefore, each electromagnetic field applier may correspond to a 1:1 voltage transformer.

According to an embodiment, the plurality of electromagnetic field appliers 341 to 348 may be connected to each other in series.

Even through the plurality of electromagnetic field appliers 341 to 348 are connected to each other in series, the coils included in each electromagnetic field applier are mutual-inductively coupled so as to form a 1:1 voltage transformer. Therefore, voltages on nodes n1 to n9 of the second plasma source 320 may have the same level.

As a result, electromagnetic fields induced by the electromagnetic field appliers may have the same intensity, and the density of plasma generated in the chamber may be regularly distributed over the circumference of the chamber.

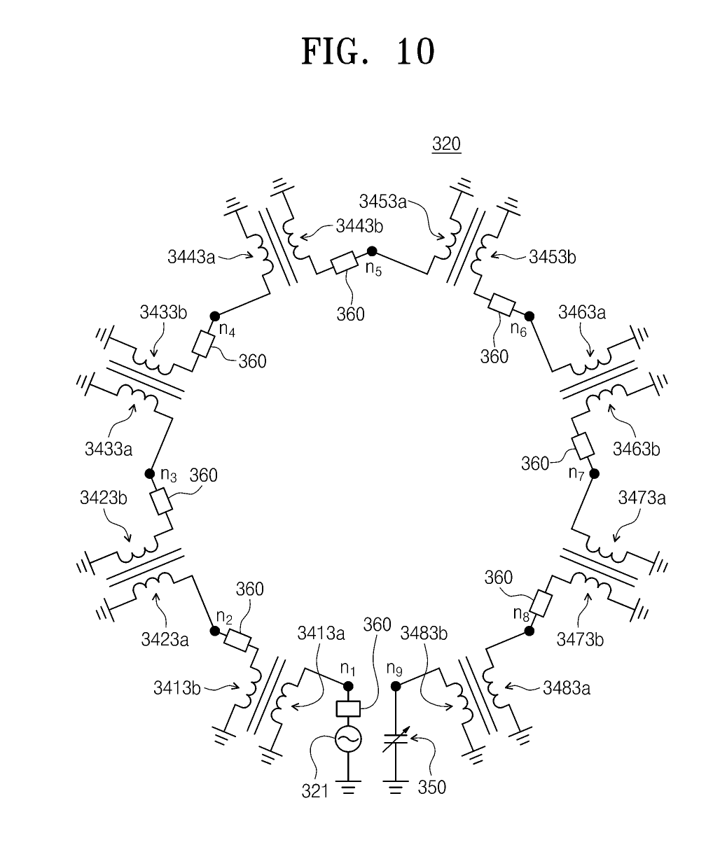

FIG. 10 is a circuit diagram illustrating an equivalent circuit of the second plasma source 320 according to the still other embodiment of the present invention.

As illustrated in FIG. 10, the second plasma source 320 may further include a phase adjuster 360. The phase adjusters 360 are provided to the nodes n1 to n8 between the RF power supply 321 and the plurality of electromagnetic field appliers 341 to 348 so as to equally fix a phase of the RF signal at each node.

According to this embodiment, the voltage on each node of the second plasma source 320 may be equally adjusted in terms of not only an amplitude but also a phase.

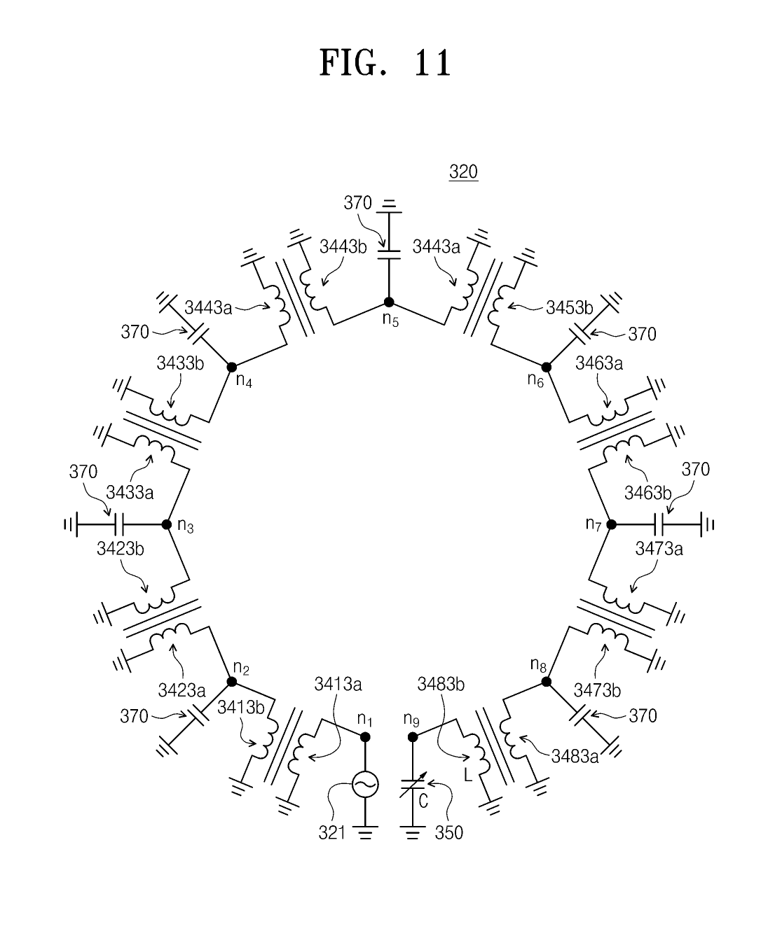

FIG. 11 is a circuit diagram illustrating an equivalent circuit of the second plasma source 320 according to a still another embodiment of the present invention.

As illustrated in FIG. 11, the second plasma source 320 may further include a shunt reactance element 370. The shunt reactance elements 370 may be connected to the nodes n2 to n8 between the plurality of electromagnetic field appliers 341 to 348. In other words, one ends of the shunt reactance elements 370 may be connected to the nodes n2 to n8 between the electromagnetic field appliers and the other ends of the shunt reactance elements 370 may be grounded.

According to an embodiment, the shunt reactance element 370 may be a capacitor that is a capacitive element, and the impedance thereof may be a half of combined impedance of a second coil L of mutual-inductively coupled coils and a reactance element C connected to a grounding terminal.

According to this embodiment, the shunt reactance element 370 may equalize a voltage of a power-supply-side input terminal of the second plasma source 320 and a voltage of a ground-side output terminal of the second plasma source 320.

According to an embodiment of the present invention, the reactance element 350 may include a variable capacitor. According to this embodiment, the second plasma source 320 may adjust the capacitance of the variable capacitor so as to control an amount of voltage drop in each electromagnetic field applier.

For example, in the case where impedance is increased by reducing the capacitance of the variable capacitor, since the amount of voltage drop in the variable capacitor is increased, the amount of voltage drop in each electromagnetic field applier is relatively decreased.

For another example, in the case where impedance is decreased by increasing the capacitance of the variable capacitor, since the amount of voltage drop in the variable capacitor is decreased, the amount of voltage drop in each electromagnetic field applier is relatively increased.

Therefore, the plasma generation unit 300 may adjust the amount of voltage drop in each electromagnetic field applier by adjusting the capacitance of the variable capacitor in order to obtain a desired density of plasma according to a substrate treatment process or an environment in the chamber.

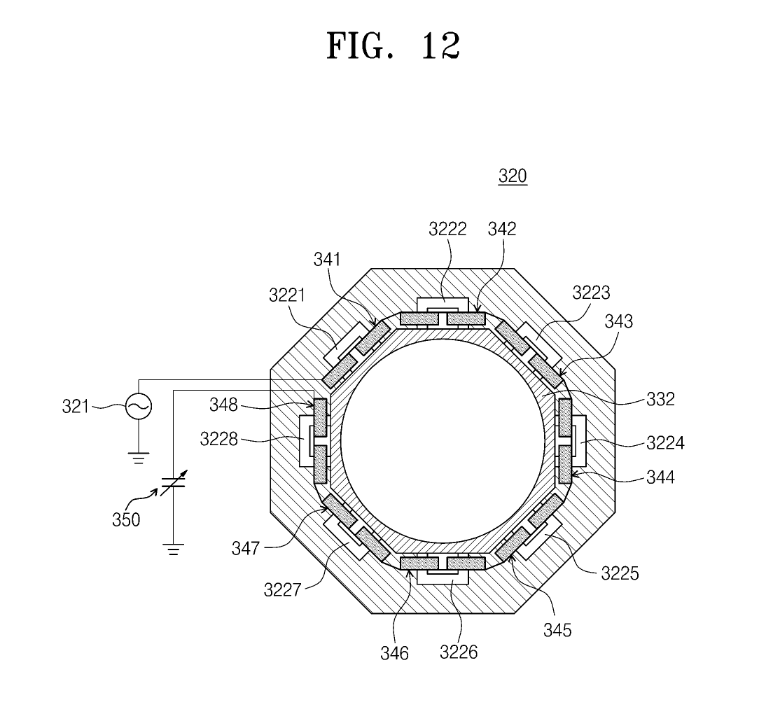

FIG. 12 is a diagram illustrating a plane view of the second plasma source 320 according to still another embodiment of the present invention.

In the embodiment illustrated in FIG. 8, the first core 3411 and the second core 3412 included in each electromagnetic field applier contacts with each other so that the first and second coils 3413a and 3413b are wound on the contact portion between the first core 3411 and the second core 3412. However, in the embodiment illustrated in FIG. 12, the first and second cores are spaced apart from each other, and the first coil is wound on one part of each core and the second coil is wound on the other part of each core.

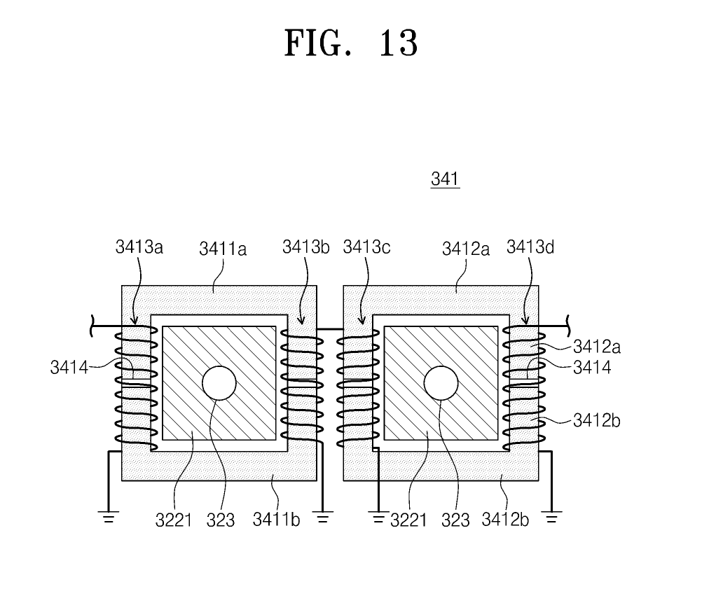

FIG. 13 is a diagram illustrating a front view of the electromagnetic field applier 341 according to still another embodiment of the present invention.

As illustrated in FIG. 13, in the electromagnetic field applier 341 according to the still other embodiment of the present invention, the first core 3411 and the second core 3412 are spaced apart from each other, and first coils 3413a and 3413c may be wound on one part of each core and second coils 3413b and 3413d may be wound on the other part of each core.

The first and second cores 3411 and 3412 form separate closed loops respectively, and the first coils 3413a and 3413c and the second coils 3413b and 3413d share one core so as to be mutual-inductively coupled.

Each coil may have the same turn number. In this case, the turn ratio between the first coils 3413a and 3413c and the second coils 3413b and 3413d is 1:1 so that each core and coils wound thereon may form a 1:1 voltage transformer.

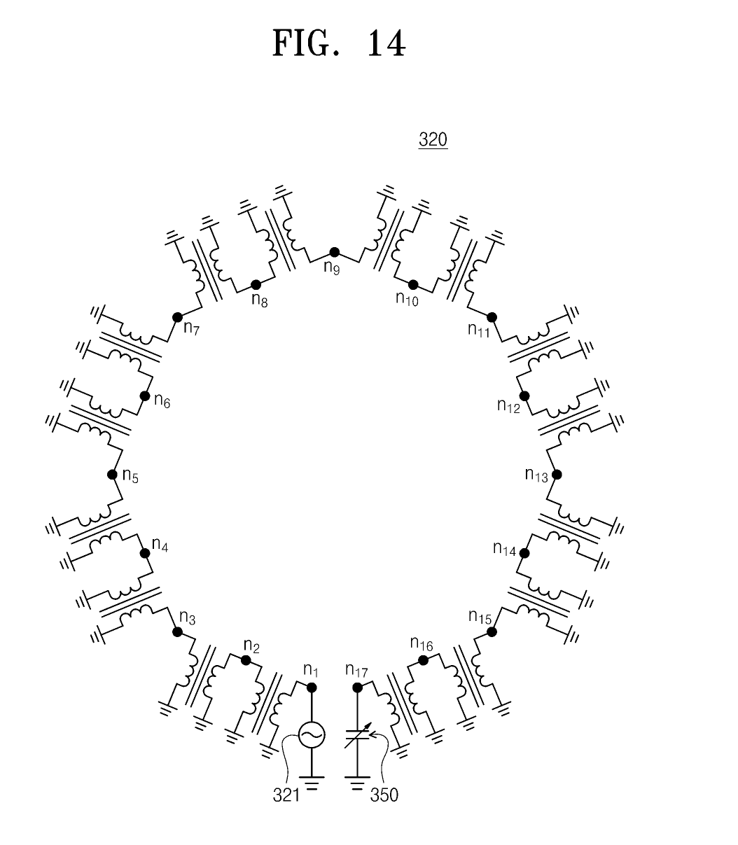

FIG. 14 is a circuit diagram illustrating an equivalent circuit of the second plasma source 320 according to the still other embodiment of the present invention.

As illustrated in FIG. 14, in the electromagnetic field appliers 341 to 348, each core and coils wound thereon may form a mutual-inductively coupled circuit so as to correspond to a 1:1 voltage transformer.

As a result, voltages on nodes n1 to n17 of the second plasma source 320 may be equally adjusted.

According to an embodiment, the phase adjusters 360 may be provided to the nodes n1 to n16 so that the phase of the RF signal may be equally fixed at each node.

According to an embodiment, one ends of the shunt reactance elements 370 may be connected to the nodes n2 to n16, wherein the other ends of the shunt reactance elements 370 may be grounded. The shunt reactance element 370 may be a capacitor that is a capacitive element, and the impedance thereof may be adjusted to be a half of combined impedance of a second coil L of mutual-inductively coupled coils and a reactance element C.

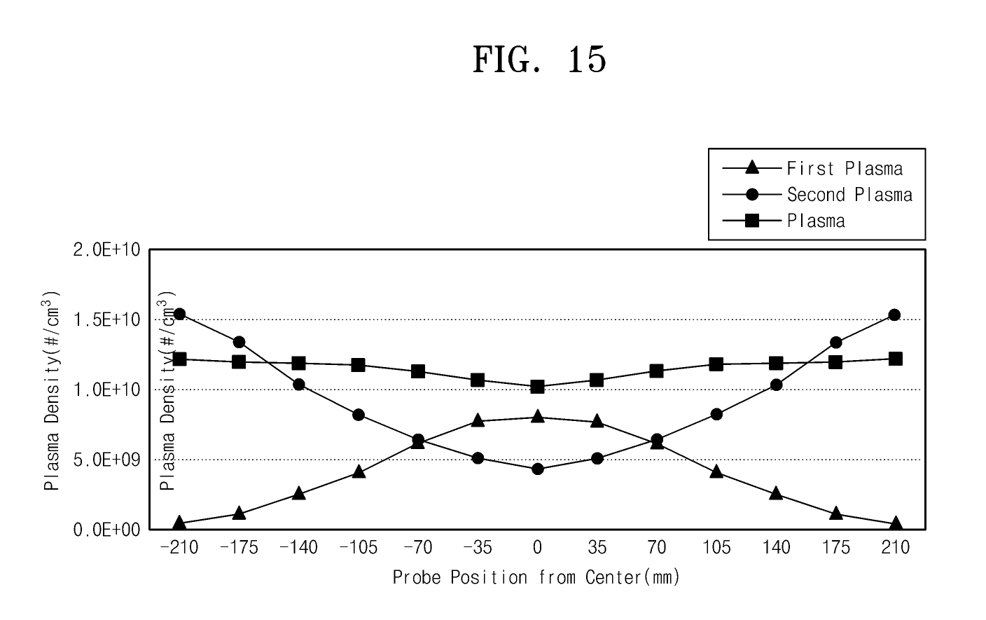

FIG. 15 is a graph illustrating density profiles of first plasma generated by the first plasma source 310, second plasma generated by the second plasma source 320, and plasma finally generated in the chamber 330 by the first and second plasma sources 310 and 320.

Referring to FIG. 15, the ICP-type or CCP-type first plasma source 310 generates the first plasma of which density is higher in a center region of the chamber 330 than in an edge region of the chamber 330.

On the contrary, the second plasma source 320 including the plurality of insulating loops 3221 to 3228 arranged along the circumference of the chamber 330 and the plurality of electromagnetic field appliers 341 to 348 generates the second plasma of which density is higher in the edge region of the chamber 330 than in the center region of the chamber 330.

As a result, the plasma generation unit 300 according to an embodiment of the present invention may generate plasma of which density is regular throughout the chamber 330 by synthesizing the first plasma and the second plasma.

Furthermore, plasma of which density is higher in the edge region of the chamber 330 than in the center region thereof may be obtained, or plasma of which density is higher in the center region of the chamber than in the edge region thereof may be obtained, by controlling the intensity of the RF power supplied to the first and second plasma sources 310 and 320.

Such controlling of the RF power may be performed by controlling the output powers of the RF power supplies 311 and 321 connected to respective plasma sources so that a ratio between the output powers becomes a predetermined ratio. According to an embodiment, if the first and second plasma sources 310 and 320 are supplied with power from one RF power supply, a power distribution circuit may be provided between the RF power and the plasma sources so as to control power supplied to each plasma source.

According to the embodiments of the present invention, plasma may be regularly generated in a chamber. In particular, even in a large chamber for treating a large-size substrate, plasma may be regularly generated, or a density profile of the plasma generated throughout the chamber may be controlled according to a process.

Furthermore, according to the embodiments of the present invention, the process yield may be improved when large-size substrates are treated.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A plasma generation apparatus comprising:
an RF power supply configured to supply an RF signal;
a plasma chamber configured to provide a space in which plasma is generated;
a first plasma source installed at one part of the plasma chamber to generate plasma; and
a second plasma source installed at the other part of the plasma chamber to generate plasma, the second plasma source comprising:
a plurality of insulating loops formed along a circumference of the plasma chamber, wherein a gas passage through which a process gas is injected and moved to the plasma chamber is provided in each insulating loop; and
a plurality of electromagnetic field appliers coupled to the insulating loops and receiving the RF signal to excite the process gas moving through the gas passage to a plasma state.

2. The plasma generation apparatus of claim 1, wherein the electromagnetic field applier comprises:
a core formed of a magnetic material and surrounding the insulating loop; and
a coil wound on the core.

3. The plasma generation apparatus of claim 2, wherein the core comprises:
a first core surrounding a first part of the insulating loop to form a first closed loop; and
a second core surrounding a second part of the insulating loop to form a second closed loop.

4. The plasma generation apparatus of claim 3, wherein the first core comprises:
a first subcore forming a half part of the first closed loop; and
a second subcore forming the other half part of the first closed loop, and
the second core comprises:
a third subcore forming a half part of the second closed loop; and
a fourth subcore forming the other half part of the second closed loop.

5. The plasma generation apparatus of claim 1, wherein the plurality of electromagnetic field appliers are connected to each other in series.

6. The plasma generation apparatus of claim 1, wherein the plurality of electromagnetic field appliers comprise a first applier group and a second applier group connected in parallel to each other.

7. The plasma generation apparatus of claim 2, wherein the plurality of electromagnetic field appliers are configured so that a turn number of the coil wound on the core is increased in a direction from an input terminal to a grounding terminal.

8. The plasma generation apparatus of claim 4, wherein the plurality of electromagnetic field appliers are configured so that a distance between the first subcore and the second subcore and a distance between the third subcore and the fourth subcore are decreased in a direction from an input terminal to a grounding terminal.

9. The plasma generation apparatus of claim 8, wherein an insulator is inserted between the first subcore and the second subcore and between the third subcore and the fourth subcore.

10. The plasma generation apparatus of claim 1, wherein
the second plasma source comprises eight electromagnetic field appliers, wherein
four of the eight electromagnetic field appliers are connected to each other in series to form a first applier group, wherein
the other four of the eight electromagnetic field appliers are connected to each other in series to form a second applier group, wherein
the first applier group is connected in parallel to the second applier group, wherein
the four electromagnetic field appliers forming the first applier group have an impedance ratio of 1:1.5:4:8, wherein
the four electromagnetic field appliers forming the second applier group have an impedance ratio of 1:1.5:4:8.

11. The plasma generation apparatus of claim 2, wherein the coil comprises:
a first coil wound on one part of the core; and
a second coil wound on the other part of the core, wherein
the first coil and the second coil are mutual-inductively coupled.

12. The plasma generation apparatus of claim 11, wherein the first coil and the second coil have the same turn number.

13. The plasma generation apparatus of claim 1, further comprising a reactance element connected to a grounding terminal of the second plasma source.

14. The plasma generation apparatus of claim 1, further comprising a phase adjusteradjuster provided to nodes between the plurality of electromagnetic field appliers to equally fix a phase of the RF signal at each node.

15. The plasma generation apparatus of claim 11, further comprising:
a reactance element connected to a grounding terminal of the second plasma source; and
a shunt reactance element connected to nodes between the plurality of electromagnetic field appliers.

16. The plasma generation apparatus of claim 15, wherein impedance of the shunt reactance element is a half of combined impedance of a secondary coil of the mutual-inductively coupled coils and the reactance element.

17. The plasma generation apparatus of claim 1, wherein the first plasma source comprises an antenna installed on the plasma chamber to induce an electromagnetic field in the plasma chamber.

18. The plasma generation apparatus of claim 1, wherein the first plasma source comprises electrodes installed in the plasma chamber to form an electric field in the plasma chamber.

19. The plasma generation apparatus of claim 17, wherein
a process gas comprising at least one of ammonia and hydrogen is injected into an upper part of the plasma chamber, wherein
a process gas comprising at least one of oxygen and nitrogen is injected into the insulating loop.

20. The plasma generation apparatus of claim 18, wherein
a process gas comprising at least one of ammonia and hydrogen is injected into an upper part of the plasma chamber, wherein
a process gas comprising at least one of oxygen and nitrogen is injected into the insulating loop.

21. A substrate treatment apparatus comprising:
a process unit comprising a process chamber and providing a space in which a process is performed, wherein a substrate is arranged in the process chamber;
a plasma generation unit configured to generate plasma and provide the plasma to the process unit; and
an exhaust unit configured to discharge gas and byproducts in the process unit, the plasma generation unit comprising:
an RF power supply configured to supply an RF signal;
a plasma chamber configured to provide a space in which plasma is generated;
a first plasma source installed at one part of the plasma chamber to generate plasma; and
a second plasma source installed at the other part of the plasma chamber to generate plasma, the second plasma source comprising:
a plurality of insulating loops formed along a circumference of the plasma chamber, wherein a gas passage through which a process gas is injected and moved to the plasma chamber is provided in each insulating loop; and
a plurality of electromagnetic field appliers coupled to the insulating loops and receiving the RF signal to excite the process gas moving through the gas passage to a plasma state.
